(19) United States
(12) Patent Application Publication
(10) Pub. No.: US 2008/0309526 A1
(43) Pub. Date: Dec. 18, 2008

(54) Method and apparatus for a simplified maximum likelihood demodulator for dual carrier modulation

(76) Inventor: Wei-Chun Wang, Temple City, CA (US)

Correspondence Address: BIRCH STEWART KOLASCH & BIRCH, PO BOX 747, FALLS CHURCH, VA, 22040-0747, US

(21) Appl. No.: 11/812,043

(22) Filed: Jun. 14, 2007

(51) Int. Cl. H03M 7/00

(52) U.S. Cl. 341/107

(57) ABSTRACT

A novel method and apparatus for wireless communication systems for simplifying the maximum likelihood (ML) Dual Carrier Modulated (DCM) demodulation for received DCM signals over frequency selective channels are disclosed. The disclosed method and apparatus are based on the Minimum Euclidean Distance (MED) decoding, which is equivalent to the maximum likelihood (ML) decoding for a frequency-selective wireless channel with Additive White Gaussian Noise (AWGN). Compared to the traditional ML decoder, the disclosed method and apparatus reduce the hypothesis testing from that of a 16 Quadrature Amplitude Modulation (16 QAM) to that of a 4 QAM, or Quadrature Phase Shift Keying (QPSK). Thus computation and hardware complexity can be reduced.

### BACKGROUND OF THE INVENTION

1. Field of the Invention

The present invention generally relates to a demodulation method and apparatus for Dual Carrier Modulation (DCM) used in wireless communication systems including the Ultra Wide Band (UWB) system, and more particularly to a simplified DCM demodulation method and apparatus to reduce the computation and hardware complexity by using a de-phasing operation before hypothesis searching.

2. Description of the Prior Art

Dual Carrier Modulation (DCM) is a modulation scheme used in wireless communication standards like ECMA-368 [1] for UWB applications. The transmitter linearly combines two independent Quadrature Phase Shift Keying (QPSK) modulated signals into two correlated 16 Quadrature Amplitude Modulation (16QAM) signals, each carrying full 4-bit information in the original QPSK pairs.

The DCM modulator modulates 4-bit data b₀, b₁, b₂, b₃ into two 16QAM signals s₀, s₁ as shown in Equation 1 below.

$$s ≡ [ \begin{matrix}{s}_{0} \\ {s}_{1}\end{matrix} ] = [ \begin{matrix}2 & 1 \\ 1 & - 2\end{matrix} ] [ \begin{matrix}{b}_{0} + {jb}_{2} \\ {b}_{1} + {jb}_{3}\end{matrix} ] \qquad Eq . ( 1 )$$

where j=\sqrt{−1}. Each bit bᵢ, i=0 to 3, can assume the value of either −1 or 1 with equal probability. The modulator output symbol sᵢ, i=0, 1, each spans a 16 QAM constellation. It is worth noting that, even though DCM uses four input bits to generate two 16 QAM symbols, these two symbols are highly correlated that each symbol alone contains the 4-bit information. A more careful examination reveals that the real parts of sᵢ only constitutes of b₀ and b₁, and the imaginary parts of sᵢ only constitutes of b₂ and b₃. In other words, if perturbed by independently distributed Additive White Gaussian Noise (AWGN), the real or imaginary parts of sᵢ, each contains the sufficient statistics of (b₀ b₁) and (b₂ b₃), respectively.

These two 16 QAM signals, when transmitted via two different frequencies over a wireless multipath propagation channel, will encounter different frequency responses. In other words, with the frequency response of each channel characterized by a complex number, the signals sent via two different frequency channels will typically have two different amplitude and phase responses when arriving at the receiver. Such a wireless propagation channel is also known as a frequency-selective propagation channel. In what follows, two complex numbers, h₀ and h₁, will be used to represent the frequency response of the two channels.

The received signal for two different frequencies

$$r ≡ [ \begin{matrix}{r}_{0} \\ {r}_{1}\end{matrix} ]$$

can be mathematically modeled as in Equation (2) below.

$$r ≡ [ \begin{matrix}{r}_{0} \\ {r}_{1}\end{matrix} ] = [ \begin{matrix}{h}_{0} & 0 \\ 0 & {h}_{1}\end{matrix} ] [ \begin{matrix}{s}_{0} \\ {s}_{1}\end{matrix} ] + [ \begin{matrix}{n}_{0} \\ {n}_{1}\end{matrix} ] \qquad Eq . ( 2 )$$

where the AWGN components n₀ and n₁ model the AWGN seen at the receiver and the channel frequency response is characterized by the channel matrix H below.

$$H = [ \begin{matrix}{h}_{0} & 0 \\ 0 & {h}_{1}\end{matrix} ] \qquad Eq . ( 3 )$$

As is shown in Eq. (3), the channel, represented by a complex pair (h₀ h₁), can be equivalently characterized by a diagonal matrix H. It should be noted that this diagonal matrix H, characterized by the frequency responses of two distinct frequency channels, can be generalized to encompass any orthogonal-channel responses encountered by employing other diversity schemes. These schemes include but are not limited to, time slots, antenna polarizations, and orthogonal codes. The optimal receiver that minimizes the received bit error rate (BER) is known to, with the assumption of equally probable transmit hypotheses and perfect channel knowledge h, employ maximum likelihood (ML) demodulation scheme which is equivalent to Minimum Euclidean Distance (MED) decoding when the noise can be characterized as AWGN.

For wireless communication standards such as ECMA-368 [1], pre-ambles are transmitted before the data portion of a packet. The pre-ambles are used for channel estimation and data portion is typically short so the channel is essentially stationary while decoding the data portion of the packet. Therefore, it can be assumed h₀ and h₁ are known at the receiver for data demodulation. Given the knowledge of the channel and equally probable transmit hypotheses, the optimal demodulation scheme is the well-known ML decoding, or equivalently the MED decoding in the presence of Additive White Gaussian Noise (AWGN) (Chapter 4, Reference [2] or pages 100 and 112, Reference [3]).

For DCM, each received signal pair carries 4-bit information. Therefore, a brute force MED decoding requires a 16 hypothesis search. The receiver calculates the Euclidean distance between the received 16 QAM pairs and the “transformed” lattice points generated from the DCM modulator and the channel, i.e., (h₀s₀, h₁s₁) as shown in Equation (4) below.

|r−Hs| for all possible s Eq. (4)

The decoded symbol, s_{ML}, is the hypothesis (set of 4-bit information) that generates the closest lattice point to the received signals. In other words,

|r−Hs_{ML}|<|r−Hs| for all s≠s_{ML} Eq. (5)

To implement MED for a traditional 16QAM signal, a receiver needs to search all 16 hypotheses to determine the minimum. Since each hypothesis testing involves a distance calculation of two complex pairs, namely (r₀, h₀s₀) and (r₁, h₁s₁), a total of 32 complex pair distance calculations are needed, with each distance computation involving complex numbers.

In Asia Pacific Conference on Communications, August, 2006, reported by Park et al., entitled “BER Analysis of Dual Carrier Modulation Based on ML Decoding” [4], a ML DCM demodulator for AWGN channels was presented. The channel frequency response was assumed to be equal for both channel frequencies. However, there was no mentioning of a frequency-selective wireless propagation channel. Neither was there any hint on optimal DCM demodulation for a frequency-selective channel.

### SUMMARY OF THE DISCLOSURE

The primary objective of the present invention is to provide a simplified DCM demodulation method for the UWB system, to reduce the computation complexity by using a de-phasing operation before hypothesis searching.

The second objective of the present invention is to provide a simplified DCM demodulation apparatus to reduce the hardware complexity by using a de-phasing operation before hypothesis searching.

In order to achieve the above objectives, the present invention provides, for received DCM signals over a frequency selective channel, a simplified ML DCM demodulation method, comprising the steps of: (i) applying a channel de-phasing operation to recover the separability of the real and imaginary parts of DCM signals; (ii) routing separately the real and imaginary parts of the de-phased DCM signals to MED decoding testing; and (iii) In each MED decoding testing, performing a hypothesis testing to find the ML decoded 2 bits of the de-phased DCM signals.

In order to achieve the second objective, the present invention provides, for received DCM signals over a frequency selective channel, a simplified ML DCM demodulation apparatus, comprising a channel de-phasing block; a first 2-bit MED based hypothesis testing block and a second 2-bit MED based hypothesis testing block. The channel de-phasing block is used to apply a channel de-phasing operation to recover the separability of the real and imaginary parts of DCM signals. The first 2-bit MED based hypothesis testing block is electrically connected to the channel de-phasing block, and used to perform a hypothesis testing to the real part of the de-phased DCM signals to find the first ML decoded 2 bits of the de-phased DCM signals. The second 2-bit MED based hypothesis testing block is also electrically connected to the channel de-phasing block and used to perform a hypothesis testing to the imaginary part of the de-phased DCM signals to find the second ML decoded 2 bits of the de-phased DCM signals.

This de-phasing operation effectively removes the phase part of the channel frequency response, thus reducing the channel frequency response into a simple attenuation. As will be shown in the detailed description, the DCM signal characteristic can be exploited and thus the ML decoding can be split into two independent parts, with 2 bit in each part.

In other words, the real and imaginary parts of the two received signals, after de-phasing operation, can be independently MED decoded to find the ML solution. Since each part contains only 2 bits, only 4 hypotheses need to be searched, which means 4 Euclidean distance calculations for each part. Totally 8 distance calculations are needed for the 4-bit ML searching with each distance computation involving only 2-dim real vectors.

The invention itself, though conceptually explained in above, can be best understood by referencing to the following description, taken in conjunction with the accompanying drawings.

### BRIEF DESCRIPTION OF THE DRAWINGS

FIG. 1 a flow chart illustrating a method for a simplified ML DCM demodulation and;

FIG. 2 a functional block diagram illustrating a simplified ML DCM demodulator.

### REFERENCES

[1] High Rate Ultra Wideband PHY and MAC Standard, ECMA-368, 1^{st} Edition, December 2005.
[2] J. Wozencraft and I. Jacobs, Principles of Communication Engineering, John Wiley & Sons, New York. 1965.
[3] M. Simon, S. Hinedi, W. Lindsey, Digital communication Techniques, Prentice Hall, Englewood Cliffs, N.J., 1995.
[4] Ki-Hong Park, Hyung-Ki Sung, and Young-Chai Ko, “BER Analysis of Dual Carrier Modulation Based on ML Decoding,” Asia Pacific Conference on Communications, August, 2006.

### DETAILED DESCRIPTION OF THE PREFERRED EMBODIMENTS

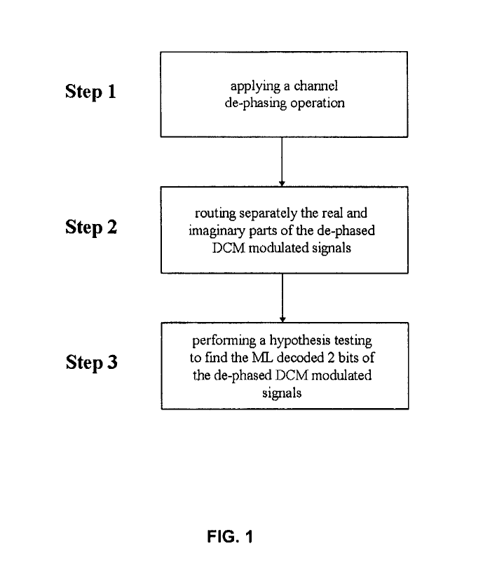

This invention proposes a simplified ML decoding with the following three steps. Referring to FIG. 1, it is a flow chart illustrating a method for a simplified ML DCM demodulation according to the present invention. The method comprises three steps.

The first step is to apply the channel de-phasing (or de-rotation) to recover the separability of the real and imaginary parts of DCM signals, which is illustrated in Equation (6) below.

$$\tilde{r} ≡ [ \begin{matrix}{\tilde{r}}_{0} \\ {\tilde{r}}_{1}\end{matrix} ] = [ \begin{matrix}\frac{{h}_{0}^{*}}{\vert {h}_{0} \vert} & 0 \\ 0 & \frac{{h}_{1}^{*}}{\vert {h}_{1} \vert}\end{matrix} ] [ \begin{matrix}{r}_{0} \\ {r}_{1}\end{matrix} ] = [ \begin{matrix}\vert {h}_{0} \vert {s}_{0} \\ \vert {h}_{1} \vert {s}_{1}\end{matrix} ] + [ \begin{matrix}{h}_{0}^{*} {n}_{0} / \vert {h}_{0} \vert \\ {h}_{1}^{*} {n}_{1} / \vert {h}_{1} \vert\end{matrix} ] \qquad Eq . ( 6 )$$

In the above, the received signal for two different frequencies

$$r ≡ [ \begin{matrix}{r}_{0} \\ {r}_{1}\end{matrix} ]$$

can be mathematically modeled as in Equation (2), s₀, s₁ are two 16QAM signals and the AWGN components n₀ and n₁ are used to model the AWGN seen at the receiver. The channel de-phasing matrix is represented by a unitary matrix U below:

$$U ≡ [ \begin{matrix}\frac{{h}_{0}^{*}}{\vert {h}_{0} \vert} & 0 \\ 0 & \frac{{h}_{1}^{*}}{\vert {h}_{1} \vert}\end{matrix} ] \qquad Eq . ( 7 )$$

where two complex numbers, h₀ and h₁ are used to represent the frequency response of the two channels transmitting the DCM signals. In the first step, each of the two received signal component gets an phase rotation opposite to what has been applied by the channel (and hence the name de-rotator), and therefore, the de-rotated received signal, \tilde{r}, has the phase rotation due to the channel frequency response removed. At the same time, the de-rotation is also applied to the complex noise vector n, with the de-rotated noise ñ below:

$$\tilde{n} ≡ [ \begin{matrix}{\tilde{n}}_{0} \\ {\tilde{n}}_{1}\end{matrix} ] = [ \begin{matrix}{h}_{0}^{*} {n}_{0} / \vert {h}_{0} \vert \\ {h}_{1}^{*} {n}_{1} / \vert {h}_{1} \vert\end{matrix} ] \qquad Eq . ( 8 )$$

By plugging the representation for s, as shown in Eq. (1), into Eq. (6), it can be readily shown that

Re{\tilde{r}₀}=|h₀|(2b₀+b₁)+Re{ñ₀}

Re{\tilde{r}₁}=|h₁|(b₀−2b₁)+Re{ñ₁} Eq. (9a)

Im{\tilde{r}₀}=|h₀|(2b₂+b₃)+Im{ñ₀}

Im{\tilde{r}₁}=|h₁|(b₂−2b₃)+Im{ñ₁} Eq. (9b)

where Re{ } and IM{ } denote taking the real part and imaginary part of the parameter inside the { }, respectively. With Equations (9a) and (9b), the benefit of applying the de-phasing matrix U, which removes the phase components of the channel frequency response, becomes obvious.

The second step is to route separately the real and imaginary parts of the de-phased DCM signals to MED decoding testing. The real and imaginary parts of the de-phased signals \tilde{r} can be separated, with each containing only 4 hypothesis lattice points perturbed by a de-rotated AWGN, which is again AWGN with the same statistics, as the de-phasing is equivalent to applying a unitary transformation to the AWGN.

The third step is to perform a hypothesis testing to find the ML decoded 2 bits of the de-phased DCM signals in each MED decoding testing. In the third step, Eq. (10a) below

(Re{\tilde{r}₀}−|h₀|(2b₀+b₁))²+(Re{\tilde{r}₁}−|h₁|(b₀−2b₁))² Eq. (10a)

can be used as the metric to search for MED solution for b₀ and b₁. Eq. (10b) below

(Re{\tilde{r}₀}−|h₀|(2b₂+b₃))²+(Re{\tilde{r}₁}−|h₁|(b₂−2b₃)) Eq. (10b)

can be used to search for MED solution for b₂ and b₃. Demodulated bits (\hat{b}₀,\hat{b}₁) is the 2-bit combination that minimizes the metric (Euclidean distance square) in Eq. (10a). Similarly demodulated bits (\hat{b}₂,\hat{b}₃) is the 2-bit combination that minimizes the metric in Eq. (10b). A total of 8 metric calculations are needed in this scheme, with each metric computation involving 2-dim real vectors. A total of 8 Euclidean distance calculations are needed in this scheme, with each Euclidean distance computation involving 2-dim real vectors.

Compared to the direct approach of prior art, the complexity of the disclosed method according to the present invention is reduced by a factor of 4. Further reductions, even if soft decisions are desired, can be easily derived with this simplified ML decoding. The reduced hypothesis searching also facilitates the generation of Log Likelihood Ratio (LLR) metric, which requires a search for the maximum likelihood metric, or equivalently MED, among all anti-hypothesis.

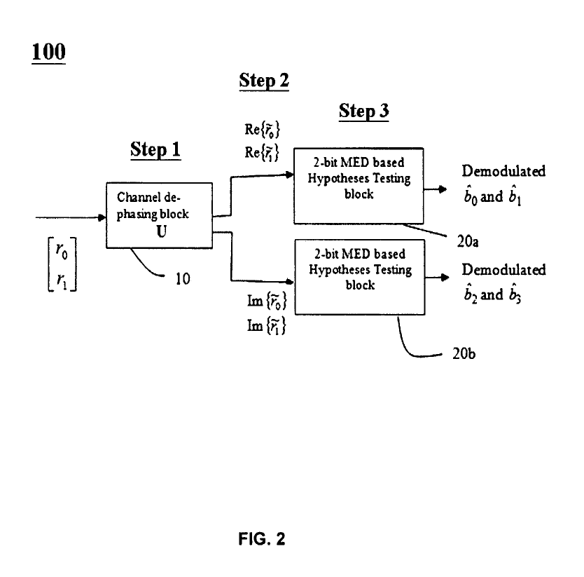

FIG. 2 is a functional block diagram illustrating a simplified ML DCM demodulator according to the present invention. The simplified ML DCM demodulator 100 has a channel de-phasing block 10 and two 2-bit MED based hypothesis testing block 20a and 20b.

The channel de-phasing block 10 is used to apply a channel de-phasing operation to recover the separability of the real and imaginary parts of DCM signals. The channel de-phasing block 10 takes the received signal r and based on an estimated channel frequency response, apply the channel de-phasing operation to the received signal according to Eq. (6). The de-phased received signal vector, \tilde{r}, then has its real part outputs, Re{\tilde{r}₀} and Re{\tilde{r}₁}, and its imaginary part outputs, Im{\tilde{r}₀} and Im{\tilde{r}₁}. The real part outputs, Re{\tilde{r}₀} and Re{\tilde{r}₁} are sent to the first 2-bit MED based hypotheses testing block 20a, and the imaginary part outputs, Im{\tilde{r}₀} and Im{\tilde{r}₁} are sent to the second 2-bit MED based hypotheses testing block 20b. The first two demodulated bits, \hat{b}₀ and \hat{b}₁, are outputs of the first 2-bit MED based hypotheses testing block 20a based on Eq. (10a). Similarly, the other two demodulated bits, \hat{b}₂ and \hat{b}₃, are outputs of the second 2-bit MED based hypotheses testing block 20a based on Eq. (10b).

It should be understood that the crux of this simplified DCM demodulator resides in applying the channel de-phasing to de-couple the real and imaginary parts of the received DCM signals, which effectively reduces the MED hypotheses testing from 32 to 8.

Accordingly, the scope of this invention includes, but is not limited to, the actual implementation of a channel de-phaser before a pair of 2-bit MED hypothesis searches for DCM demodulation. Although the invention has been explained in relation to its preferred embodiment, it is not used to limit the invention. It is to be understood that many other possible modifications and variations can be made by those skilled in the art without departing from the spirit and scope of the invention as hereinafter claimed. For example, any attempt to convert the channel effects from complex to real in order to reduce the size of hypothesis testing for DCM demodulation should be regarded as utilizing de-phasing operation.

What is claimed is:

1. A method for simplifying the maximum likelihood (ML) Dual Carrier Modulated (DCM) demodulation for received DCM signals over frequency selective channels, comprising the steps of:
(i) applying a channel de-phasing operation to recover the separability of the real and imaginary parts of DCM signals;
(ii) routing separately the real and imaginary parts of the de-phased DCM signals to Minimum Euclidean Distance (MED) decoding testing; and
(iii) In each MED decoding testing, performing a hypothesis testing to find the ML decoded 2 bits of the de-phased DCM signals.

2. The method as claimed in claim 1, wherein the first step of applying a channel de-phasing operation uses a unitary channel de-phasing matrix to DCM signals to get a phase rotation.

3. The method as claimed in claim 2, wherein the unitary channel de-phasing matrix is
$$U ≡ [ \begin{matrix}\frac{{h}_{0}^{*}}{\vert {h}_{0} \vert} & 0 \\ 0 & \frac{{h}_{1}^{*}}{\vert {h}_{1} \vert}\end{matrix} ]$$
where two complex numbers, h₀ and h₁ are used to represent the frequency response of the two channels transmitting the DCM signals.

4. The method as claimed in claim 1, wherein the third step of performing a hypothesis testing uses a pair of 4 hypothesis searches for the real and imaginary parts of the de-phased DCM signals.

5. The method as claimed in claim 1, wherein the method is used in wireless communication standards like ECMA-368 for UWB applications.

6. An apparatus for simplifying the ML DCM demodulation for received DCM signals over frequency selective channels, comprising:
a channel de-phasing block, used to apply a channel de-phasing operation to recover the separability of the real and imaginary parts of DCM signals;
a first 2-bit MED based hypothesis testing block, electrically connected to the channel de-phasing block, used to perform a hypothesis testing to the real part of the de-phased DCM signals to find the first ML decoded 2 bits of the de-phased DCM signals; and
a second 2-bit MED based hypothesis testing block, electrically connected to the channel de-phasing block, used to perform a hypothesis testing to the imaginary part of the de-phased DCM signals to find the second ML decoded 2 bits of the de-phased DCM signals.

7. The apparatus as claimed in claim 6, wherein the channel de-phasing block uses a unitary channel de-phasing matrix to DCM signals to get an phase rotation.

8. The apparatus as claimed in claim 7, wherein the unitary channel de-phasing matrix is
$$U ≡ [ \begin{matrix}\frac{{h}_{0}^{*}}{\vert {h}_{0} \vert} & 0 \\ 0 & \frac{{h}_{1}^{*}}{\vert {h}_{1} \vert}\end{matrix} ]$$
where two complex numbers, h₀ and h₁ are used to represent the frequency response of the two channels transmitting the DCM signals.

9. The apparatus as claimed in claim 6, wherein the third step of performing a hypothesis testing uses a pair of 4 hypothesis searches for the real and imaginary parts of the de-phased DCM signals.

10. The apparatus as claimed in claim 6, wherein the apparatus is used in wireless communication standards like ECMA-368 for UWB applications.
